(19) United States
(12) Patent Application Publication
(10) Pub. No.: US 2024/0178834 A1
(43) Pub. Date: May 30, 2024

(54) Drive Voltage Generator

(71) Applicants: NEXPERIA B.V., Nijmegen (NL); Nexperia Technology (Shanghai) Ltd., Shanghai (CN)

(72) Inventor: Loveday Haachitaba Mweene, Dallas, TX (US)

(73) Assignees: NEXPERIA B.V., Nijmegen (NL); Nexperia Technology (Shanghai) Ltd., Shanghai (CN)

(21) Appl. No.: 18/522,571

(22) Filed: Nov. 29, 2023

(30) Foreign Application Priority Data
Nov. 29, 2022 (EP) 22210140.4

(51) Int. Cl. H03K 17/30

(52) U.S. Cl. CPC H03K 17/302; H01L 29/2003; H03K 2217/0081

(57) ABSTRACT

According to an aspect of the present disclosure, a drive voltage generator for driving a GaN high electron mobility transistor is provided. According to another aspect there is provided a GaN high electron mobility transistor unit including a GaN high electron mobility transistor, and a drive voltage generator connected to the GaN high electron mobility transistor. A method for generating a drive voltage for a GaN high electron mobility transistor is also provided.

### CROSS-REFERENCE TO RELATED APPLICATIONS

This application claims the benefit under 35 U.S.C. § 119(a) of European Application No. 22210140.4 filed Nov. 29, 2022, the contents of which are incorporated by reference herein in their entirety.

### BACKGROUND

### 1. Field of the Disclosure

The present disclosure relates to a drive voltage generator for driving a gallium nitride GaN high electron mobility transistor HEMT. In particular, it relates to a drive voltage generator able to take an input square wave and translate the low voltage to a negative voltage, and translate the high voltage to a higher voltage.

### 2. Description of the Related Art

It is known in the field of power electronics that enhancement mode GaN (also referred to as eGaN) HEMT is a power switch technology that is promising as a replacement for silicon and silicon carbine MOSFETs in some applications. E-mode GaN HEMTs may enable faster switching and better efficiency in many applications, leading to the development of smaller systems.

Compared to silicon technologies, E-mode GaN HEMT may have a low threshold voltage (e.g. of about 1V) at which a current >1-10 mA starts flowing. Silicon MOSFETs in contrast, may have a threshold voltage in a range of 3V to 5V. Furthermore, the gate to source (or gate-source) voltage at which a GaN HEMT is fully conductive (e.g. typically 5V-6V) may be high compared to the supply voltages which are available in systems where eGaN HEMTs are being used. As a result, it may be challenging to drive a GaN with a standard power line, such as a 0-3.3V supply used to power a 3.3V microcontroller. Providing separate power rails to drive the eGaN HEMT is possible, but can add significant cost and complexity to the system.

It is an object of the present disclosure to overcome or mitigate a problem associated with the prior art. In “A gate Driver with a Negative Turn Off Bias Voltage for GaN HEMTs” Hang Zhou et al. describe a negative turn-off bias generator with a charge pump based approach, offering a stable negative turn-off voltage under different switching frequencies and duty cycles. U.S. Ser. No. 10/361,698B2 describes a gate drive circuit for generating asymmetric drive voltages with a gate driver transformer.

### SUMMARY

According to a first aspect of the present disclosure, there is provided a drive voltage generator for driving a GaN high electron mobility transistor. The drive voltage generator comprises a fixed input configured to receive fixed voltage, and a square wave input configured to receive a square wave voltage alternating between a high voltage and a low voltage. The drive voltage generator further comprises a first capacitor connected to the square wave input, a first circuit connected to the fixed input, and a first transistor connected to the first capacitor and the first circuit. The drive voltage generator further comprises a second capacitor connected to the square wave input, a second circuit connected the fixed input, and a second transistor connected to the second capacitor and the second circuit. The generator is configured to, when the square wave voltage is low, load, by the first circuit, the first capacitor with a portion of the fixed voltage, and keep, by the first circuit, a gate-source voltage of the first transistor below a first threshold voltage of the first transistor.

When the square wave voltage is high, the generator adds the high voltage to the portion of the fixed voltage of the first capacitor and increase the gate-source voltage of the first transistor above the first threshold voltage, such that the high voltage and the portion of the fixed voltage of the first capacitor is provided through the transistor as an output voltage of the drive voltage generator. When the square wave voltage is high, the second circuit loads the second capacitor with a portion of the high voltage. The second circuit keeps a gate-source voltage of the second transistor below a second threshold voltage of the first transistor. When the square wave voltage is low, the generator reduces the load of the second capacitor by the high voltage such that it becomes a negative voltage and increases the gate-source voltage of the second transistor above the second threshold voltage, such that the negative voltage of the second capacitor is provided through the second transistor as an output voltage of the drive voltage generator.

Optionally, the high voltage may be 3.3V and the low voltage may be 0V.

Optionally, the output voltage may be in a range from 4.5V to 6.6V when the square wave voltage is high.

Optionally, the output voltage may be in a range from 5V to 6.6V.

Optionally, the output voltage may be in a range of −1.5V to −3.3V when the square wave voltage is low.

Optionally, the output voltage may be in a range from −2V to −3V.

Optionally, the first circuit may comprise a series connection of a regular diode and a Zener diode connected to the fixed voltage.

Optionally, the second circuit may comprise a series connection of a regular diode and a Zener diode connected to a ground.

Optionally, the square wave voltage may be provided by a microcontroller.

Optionally, the first and second transistors may be bipolar junction transistors. The gate-source voltage may be a base-emitter voltage.

According to another aspect of the current disclosure there is provided a GaN high electron mobility transistor unit comprising a GaN high electron mobility transistor, and a drive voltage generator as described above connected to the GaN high electron mobility transistor. The output voltage of the drive voltage generator may be a supply voltage to the GaN high electron mobility transistor.

According to another aspect of the current disclosure there is provided a method for generating a drive voltage for a GaN high electron mobility transistor. A fixed voltage is received. A square wave voltage alternating between a high voltage and a low voltage is received. When the square wave voltage is low a first circuit connected to a first capacitor loads (charges) the first capacitor with a portion of the fixed voltage. The first circuit keeps a gate-source voltage of a first transistor connected to the first capacitor and the first circuit below a first threshold voltage of the first transistor. When the square wave voltage is high, the high voltage is added to the portion of the fixed voltage of the first capacitor, and the gate-source voltage of the first transistor is increased above the first threshold voltage, such that the high voltage and the portion of the fixed voltage of the first capacitor is provided through the transistor as an output voltage of the drive voltage generator. Further, when the square wave voltage is high a second circuit loads (charges) a second capacitor connected to the second circuit with a portion of the high voltage. The second circuit keeps a gate-source voltage of a second transistor connected to the second capacitor and the second circuit below a second threshold voltage of the second transistor. When the square wave voltage is low the load of the second capacitor is reduced by the high voltage such that it becomes a negative voltage. The gate-source voltage of the second transistor is increased above the second threshold voltage, such that the negative voltage of the second capacitor is provided through the second transistor as an output voltage of the drive voltage generator.

Features of different aspects of the disclosure may be combined together.

### BRIEF DESCRIPTION OF THE DRAWINGS

Embodiments of the disclosure will now be described, by way of example only, with reference to the accompanying schematic drawings, in which:

FIG. 1 schematically depicts a drive voltage generator circuit.

FIG. 2 schematically depicts a drive voltage generator connected to a microcontroller and a GaN transistor.

FIG. 3 schematically depicts a specific implementation of a drive voltage generator circuit.

FIG. 4 depicts a flow diagram of a method for generating a drive voltage for a GaN high electron mobility transistor.

### DETAILED DESCRIPTION

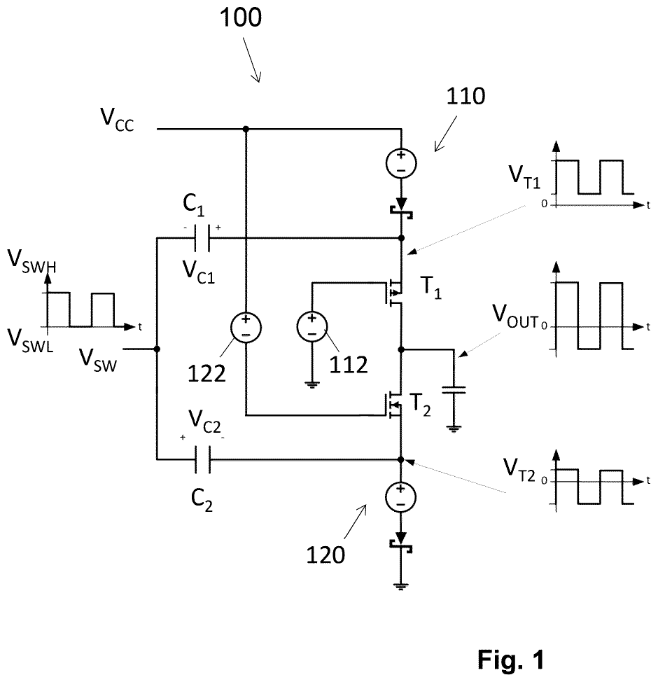

FIG. 1 schematically depicts a drive voltage generator 100 circuit. The drive voltage generator may be for providing a drive voltage for a gallium nitride GaN high electron mobility transistor HEMT. The drive voltage generator may provide a drive voltage for a GaN HEMT as an output voltage V_{OUT}. The drive voltage generator 100 may receive as input a fixed input V_{CC}. The input voltage may be a fixed DC voltage V_{CC}. The drive voltage generator 100 may further receive as input a square wave voltage V_{SW}. The square wave voltage may be a voltage provided by a pulse width modulator. The square wave voltage may switch/alternate between a high voltage V_{SWH} and a low voltage V_{SWL}.

A first capacitor C₁ is provided connected to the square wave input V_{SW}. The first capacitor C₁ may be referred to as a positive capacitor, as the aim of the circuit 100 is to charge it to a voltage that is higher than the high voltage of the square wave input V_{SWH}. This may be a voltage that helps increase the high value of V_{OUT} from V_{SWH} to a positive value greater than V_{CC}. The first capacitor C₁ is further connected to a first circuit 110. The first circuit 110 may be referred to as the positive circuit. The first circuit 110 is connected to the fixed input V_{CC}. The first circuit may be designed to have a desired fixed voltage across it when V_{SW} is in the high state. The desired fixed voltage across the first circuit 110 may be referred to as V₁₁₀, and may be such that:

V₁₁₀=V_{CC}−V_{C1}.

V_{C1} may be such that:

V_{C1}+V_{SWH}=V_{OUT}

wherein V_{OUT} may be in a range of >3.3V to 6.6V, as explained below).

A first transistor T₁ is connected to the first circuit 110 and to the first capacitor C₁. The first transistor may be a MOSFET. The first transistor T₁ may be a p-type MOSFET. The first circuit 110 is depicted in FIG. 1 as comprising several elements, and may refer to a one or more elements in the circuit used to manage the voltages provided to the different ports of the first transistor T₁.

A second capacitor C₂ is provided connected to the square wave input V_{SW}. The second capacitor C₂ may be referred to as a negative capacitor, as the aim of the circuit 100 is to load it with a voltage that helps to shift the low value of V_{OUT} from zero to a desired negative value. The second capacitor C₂ is further connected to a second circuit 120. The second circuit may be referred to as the negative circuit. The second circuit 120 may be connected (directly or indirectly) to the fixed power supply V_{CC}. A second transistor T₂ is connected to the second circuit 120 and to the second capacitor C₂. The second transistor may be a MOSFET. The second transistor T₂ may be an n-type MOSFET. The second circuit 120 is depicted in FIG. 1 as comprising several elements and may refer to a one or more elements in the circuit used to manage the voltages provided to the different ports of the first transistor T₂.

The first transistor T₁ is configured to provide the peak value of the voltage V_{T1} to the output V_{OUT} when the gate of the first transistor T₁ turns the transistor on, such that V_{OUT} is connected to a positive end of C₁. This occurs when the square wave input V_{SW} is in the high state V_{SWH}. The voltage provided as V_{T1} is higher than the high voltage V_{SWH} provided as square wave input. It achieves this as follows: when the square wave V_{SW} voltage is low, V_{CC} and first circuit 110 charge the capacitor C₁ to a voltage of V_{C1}. When V_{SW} goes high to V_{SWH}, the voltage V_{T1} becomes substantially equal to the sum of V_{C1} and V_{SWH}. This may be equal to the desired gate voltage. Element/circuit 112 may have a voltage that is such that it allows T₁ to turn on when V_{SW} is high. Circuit 112 may further be configured such that it forces transistor T₁ to turn off when V_{SW} is low. The portion of the fixed voltage loaded onto the first capacitor V_{C1} may be referred to as positive voltage V_{POS}. When the square wave input is low V_{SWL}, the first circuit 110 may further manage that a voltage between the gate and the source (gate-source voltage V_{GS1}) of the first transistor is lower than a threshold voltage for turning T₁ on.

The second transistor T₂ is configured to provide a voltage V_{T2} to the output V_{OUT} when the gate of the second transistor T₂ turns it on, such that a source voltage of the low value of V_{T2} is connected to the output voltage V_{OUT}. This occurs when the square wave input V_{SW} is in the low state V_{SWL}. The voltage provided as V_{T2} may be generated as follows: capacitor C₂ may be configured to store a voltage. While V_{SW} is high, the capacitor C₂ may charge to a voltage V_{C2} wherein:

V_{C2}=V_{SWH}−V₁₂₀,

with V₁₂₀ being a portion of the voltage loaded over the second circuit 120. When V_{SW} goes low the left hand side of C₂ is brought to 0V potential. Therefore, the right hand side is brought to a voltage of −V_{C2} (equal to −V₁₂₀). This may be loaded as the gate voltage that applies to V_{OUT}.

As V_{SW} is 0 in many implementations, this means V_{T2} provided to V_{OUT} is a negative voltage. The generator 100 achieves this by, when the square wave voltage is high, having the second circuit 120 connect a portion of the fixed voltage V_{CC} to the gate of T₂. The high voltage V_{SWH} is also connected to the second capacitor C₂. The second circuit 120 further reduces the voltage stored onto second capacitor C₂ to be less than V_{SWH}. The portion of the high voltage V_{SWH} loaded onto the second capacitor V_{C2} may be referred to as negative voltage V_{NEG}. Note that V_{NEG} may be a positive voltage (e.g. V_{SWH}−V₁₂₀, as described above). When the square wave input is high V_{SWH}, the second circuit 120 may further manage that a voltage between the gate and the source (gate-source voltage V_{GS2}) of the second transistor T₂ is lower than a threshold voltage for turning T₂ on.

When the square wave input V_{SW} switches to its low voltage state, the voltage difference (V_{SWH}−V_{SWL}) is subtracted from the voltage loaded onto the second capacitor C₂, loaded onto the second capacitor during the low voltage state. As the subtracted voltage amount is larger than the voltage stored on second capacitor during the high voltage state, the resulting voltage stored on second capacitor is negative: −V_{C2}. The second circuit 120 may be configured to provide this voltage −V_{C2} to the transistor so that V_{T2}=−V_{C2}. The second circuit 120 is also configured to achieve that in response to the square wave input going low, the gate-source voltage V_{GS2} of the first transistor T₂ goes above the threshold voltage, so that T₂ turns on. As a result of T₂ turning on, the voltage V_{T2} is connected to the generator output and provided as V_{OUT}, during the square wave input V_{SW} low state.

In the implementations described herein, V_{CC} may be a DC voltage having a value of 3.3V. Other DC voltage values may be provided. The square wave may switch between 0V and 3.3V. The voltage V_{SW} may be provided by a unipolar rail. The voltage may for example be provided by a microcontroller.

The first capacitor C₁ may draw the first capacitor voltage V_{C1} up to a value in a range from V_{SWH} to twice the value of the high square wave voltage V_{SWH}. In an example where the square wave is a 0-3.3V square wave, V_{C1} may be in a range from >3.3V to 6.6V. The first capacitor voltage may preferably be in a range from 5V to 6.6V, or in a range from 5V to 6V. These voltages may be provided as V_{T1}, and as a result as V_{OUT}, while the square wave input state is high. The 5V value may be of interest for turning on a GaN HEMT.

The second capacitor C₂ may draw the second capacitor voltage V_{C2} down from 0 to a negative value −V₁₂₀. In an example where the square wave is a 0-3.3V square wave, −V_{C2} may be in a range from <0V to −3.3V. The second capacitor voltage −V_{C2} may preferably be in a range from −2V to −3.3V, or in a range from −2V to −3V. These voltages may be provided as V_{T2}, and as a result as V_{OUT} while the square wave input state is low.

The capacitors C₁ and C₂ may be made large enough in value so that they hold their charge during normal switching operation (e.g. pulse width modulator PWM square wave switching 0-3.3V). Large enough may for example be in a range from 10 nF to the order of 1 μF, or higher. During operation, the capacitors C₁ and C₂ hold voltages V_{POS} and −V_{NEG} when the square wave input state is low, and switch to V_{POS}+V_{SWH} and V_{SWH}−V_{NEG} when the square wave input is high.

Element 112 may form part of the first circuit 110 for controlling and directing the voltage on first capacitor C₁ and first transistor T₁. Element 112 may bias the first transistor to be off while the square wave input state is low. Element 122 may form part of the second circuit 120 for controlling and directing the voltage on the second capacitor C₂ and the second transistor T₂. Element 122 may bias the second transistor to be off while to square wave input state is high. When the square wave output is high, the voltage applied to the gate of transistor T₁ may be greater than its threshold voltage, and the first transistor T₁ may be turned on; the gate voltage of transistor T₂ may be less than its threshold voltage, turning the second transistor T₂ off. When the square wave output is low, the voltage applied to the gate of T₂ may be greater than its threshold voltage, and the second transistor T₂ may be turned on; the gate voltage of the first transistor may be less than its threshold voltage, turning the first transistor T₁ off.

GaN or eGaN (enhancement GaN) high electron mobility transistors (HEMTs) are power switching devices which may have significant speed, efficiency, and/or size advantages over their silicon counterparts in switching power supplies. The terminal arrangement and drive requirements of GaN HEMTs may be similar to those of silicon. A challenge with (e)GaN HEMTs is that they may require a low, tightly controlled voltage from 5V to 6V to turn on completely. Their gate threshold voltage meanwhile may be low from around 1V-2V. The low threshold voltage compared to silicon transistors means GaN HEMTs may be susceptible to unwanted noise, that may turn the transistor on and off. Furthermore, GaN HEMTs may frequently be applied in systems where their gate drive signal originates from standard electronics components (e.g. from a microcontroller). These standard electronic components often provide an output voltage of 3.3V or less, which is not high enough to turn them on.

A problem of low threshold voltage may be solved by making the off-state voltage of the HEMT negative, rather than zero. That way, the effective threshold voltage may be increased; e.g. instead of a 1V threshold voltage (between 0V to 1V), a 3V threshold voltage (between −2V and 1V). A problem of the 3.3V high state voltage being too low to fully turn on a GaN HEMT may be solved by feeding standard electronic output component output into a separate driver that powers the HEMT. To generate outputs of 5V, and say, −2V, such a driver may require two rails to generate these (negative and higher positive) voltages. This solution of providing additional power rails may add significant cost and complexity to the system.

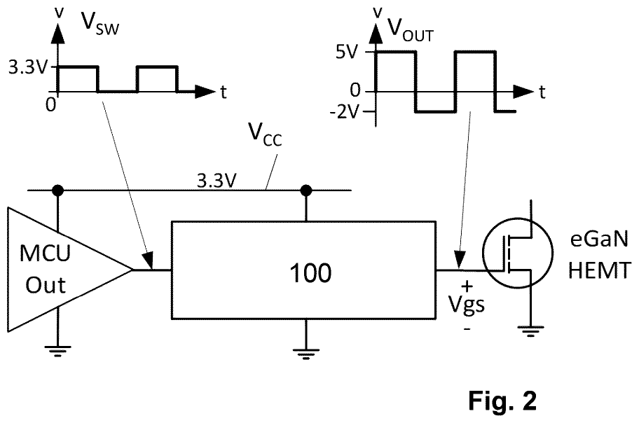

The drive voltage generator described here provides a technique to generate a gate drive signal with an on-state voltage greater than 3.3V (e.g., 5V-6V), and a negative off-state voltage (e.g., −2V-−3V) without the use or need of any supply rails other than the 3.3V square wave signal. This technique is presented here in its MOSFET implementation, but a bipolar BJT equivalent has also been shown to function equivalently. FIG. 2 depicts a schematic representation of an application using the drive voltage generator 100 as described in relation to FIG. 1. A microcontroller MCU may provide a 0-3.3 V square wave output signal. A 3.3V DC rail may be provided as power supply at the microcontroller MCU. The microcontroller output signal may be the square wave signal V_{SW}. The fixed voltage V_{CC} may be provided from the same power supply rail of the microcontroller. V_{SW} and V_{CC} signals may be provided to the drive voltage generator 100 to be translated into a −2V to 5V signal with a square wave shape substantially corresponding to the square wave of the square wave signal. The output signal of generator 100 V_{OUT} may be provided as a drive signal for an eGaN HEMT.

Advantages of the solution using a generator as described in relation to FIG. 1 may be that the circuit may be made entirely of passive components and discrete semiconductors. Generator 100 may increase the positive swing of the square wave signal VSW from 3.3 V to 5V without changing the waveform shape, and without introducing delays. Generator 100 may change the low state voltage from 0 V to −2V. Generator 100 may accomplish both of these things using only the existing 3.3V microcontroller power rail and the output signal of the microcontroller rail.

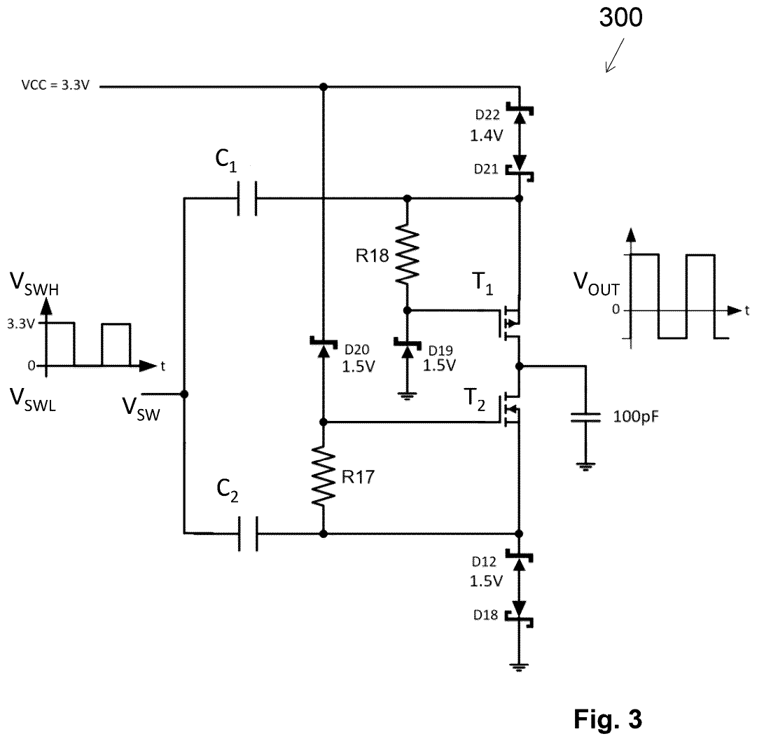

A specific implementation of a drive voltage generator 300 is shown in FIG. 3. The labels may correspond to the labels described in relation to FIG. 1. The description provided in relation to FIG. 1 above applies to the features of FIG. 3 as well. Specific implementations of the first circuit 110 and the second circuit 120 are depicted. These may include diodes D12, D18, D19, D20, D21, and D22. D12, D19, D20, and D22 may be Zener diodes. D18 and D21 may be regular diodes. D18 and D21 may be Schottky diodes. Capacitors C₁ and C₂ may have a capacitance in a range from 1 nF to 1 μF. R17 and R18 may for example have values of 1 kΩ.

Capacitor C₁, transistor T₁, resistor R18, and diodes D19, D21, D22 may be referred to as the positive voltage generator circuit. The positive voltage generator circuit may work as follows: when V_{SW} is low (V_{SWL}=0V), there is a fixed voltage V_{CC} connected to C₁, via diodes D21 and D22. C₁ may have a right hand side (facing towards V_{CC}) positive. The right hand side positive voltage of C₁ may be equal to V_{CC} minus the forward drop of D21 minus the reverse drop of D22. In an example implementation V_{forward}(D21)=0.3V and Vᵣₑᵥₑᵣₛₑ(D22)=1.3V; therefore, when V_{SW} is 0V, V_{C1}=3.3V−1.3V−0.3V=1.7V. In combination with the voltage over D19 (1.5V), the gate-source voltage V_{GS1} over first transistor T₁ is below the threshold for turning on first transistor T₁. D21 may be a Schottky diode.

When V_{SW} goes high (to V_{SWH}=3.3V), two things happen. The first thing to happen is the voltage on the right hand side of the capacitor increases by the amount V_{SWH}, so that V_{C1}=1.7V+3.3V=5.0V. This can be because the capacitance of C₁ is large enough so that the V_{CC} voltage may remain on C₁ for typical switching frequencies of V_{SW}. The second thing to happen is the gate source voltage V_{GS1} on the first transistor T₁ goes high so that the transistor turns on. The voltage V_{C1}=5.0V is connected from the source to the drain of T₁ and linked to V_{OUT} of the voltage generator 300. During the time V_{SW} is in the high state, the second transistor T₂ is off because the breakdown voltage of diode D20 keep the gate voltage of T₂ below threshold.

Capacitor C₂, transistor T₂, resistor R17, and diodes D20, D18, and D12 may be referred to as the negative voltage generator circuit. The negative circuit generator circuit may work as follows: when V_{SW} is high (V_{SWH}=3.3V), the 3.3V is loaded onto the second capacitor C₂, with the left hand side being positive. The voltage across C₂ is therefore V_{SWH} minus the reverse voltage of diode D12 and the forward voltage of diode D18: V_{C2}=V_{SWH}−Vᵣₑᵥₑᵣₛₑ(D12)−V_{forward}(D18). In an example implementation Vᵣₑᵥₑᵣₛₑ(D12)=1.5V and V_{forward}(D18)=0.3V; therefore, when V_{SW}=3.3V, V_{C2}=3.3V−1.5V−0.3V=1.5V.

When V_{SW} goes to low (V_{SWL}=0V), D19 keeps the first transistor T₁ gate-source voltage V_{GS} below threshold, so T₁ is off. When V_{SW} goes down to 0V, the source voltage of T₂ is pulled down to −1.5V, turning the gate-source voltage V_{GS} above threshold. Second transistor T₂ is turned on and the negative voltage is transmitted to V_{OUT}.

As described above, first circuit 110 and/or second circuit 120 may comprise a series connection of a Zener diode and a regular diode. The regular diode may alternatively be a Schottky diode. The first circuit 110 may comprise a series connection of a regular diode and a Zener diode connected to the fixed voltage V_{CC}. The second circuit 120 may comprise a series connection of a regular diode and a Zener diode connected to a ground.

It may be noted that the current that is required to be provided to the HEMT gate voltage V_{OUT} may come from the output of a microcontroller logic gate. However, the output current capability of many such devices may be low, and may be unable to switch a GaN HEMT fast enough. In such cases, the switching waveform from the microcontroller may be fed first to a current-boosting driver before being processed by the drive voltage generator described herein. This driver may operate from the V_{CC} 3.3V rail. This driver may also be provided as part of the drive voltage generator, for example on a same or linked integrated circuit.

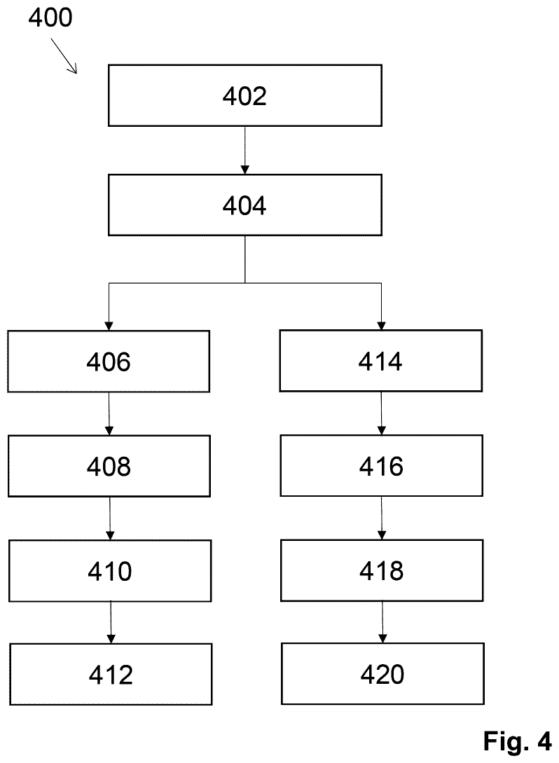

FIG. 4 depicts a flow diagram of a method 400 for generating a drive voltage for a GaN high electron mobility transistor. The method comprises receiving 402 a fixed voltage V_{CC}, and receiving 404 a square wave voltage V_{SW} alternating between a high voltage V_{SWH} and a low voltage V_{SWL}. When the square wave voltage is low V_{SWL}: loading 406, by a first circuit 110 connected to a first capacitor C₁, the first capacitor C₁ with a portion of the fixed voltage V_{CC}. The first circuit also keeps 408 a gate-source voltage V_{GS1} of a first transistor T₁ connected to the first capacitor C₁ and the first circuit 110 below a first threshold voltage of the first transistor T₁. When the square wave voltage is high V_{SWH}, the high voltage is added 410 to the portion of the fixed voltage of the first capacitor C₁. The gate-source voltage V_{GS1} of the first transistor T₁ is increased 412 above the first threshold voltage, such that the high voltage and the portion of the fixed voltage of the first capacitor C₁ is provided through the transistor T₁ as an output voltage V_{OUT} of the drive voltage generator.

When the square wave voltage is high, loading 414 by a second circuit 120, a second capacitor C₂ connected to the second circuit 120, with a portion of the high voltage V_{SWH}. The second circuit keeps 416 a gate-source voltage V_{GS2} of a second transistor T₂ connected to the second capacitor C₂ and the second circuit 120 below a second threshold voltage of the second transistor T₂. When the square wave voltage is low, the load of the second capacitor C₂ is reduced 418 by the high voltage such that it becomes a negative voltage. The gate-source voltage of the second transistor is increased 420 above the second threshold voltage, such that the negative voltage of the second capacitor C₂ is provided through the second transistor T₂ as an output voltage of the drive voltage generator.

It should be noted that the specific voltage levels and values mentioned above are for illustration only, and that the methods, circuits, and apparatus described herein may also work at other voltages suitable for specific components needs. Specifically, using the generator circuit 100 described herein the positive voltage may be raised to any desired value up to twice the provided microcontroller rail voltage. The negative voltage may be lowered to any value down to the inverse of the positive rail voltage provided.

The electronic circuits depicted and described in this application are provided as examples only, and the skilled person would understand that alternative circuit configurations may be designed that achieve equivalent effects.

Although described herein in relation to MOSFET transistor technology, it is provided that the voltage generators and methods described herein may be implemented for bipolar junction transistors as well using equivalent concepts and solutions as described in relation to MOSFETs.

What is claimed is:

1. A drive voltage generator for driving a GaN high electron mobility transistor, comprising:
a fixed input configured to receive a fixed voltage;
a square wave input configured to receive a square wave voltage alternating between a high voltage and a low voltage;
a first capacitor connected to the square wave input, a first circuit connected to the fixed input, and a first transistor connected to the first capacitor and the first circuit; and
a second capacitor connected to the square wave input, a second circuit connected the fixed input, and a second transistor connected to the second capacitor and the second circuit;
wherein the generator is configured to:
load the first capacitor by the first circuit with a portion of the fixed voltage when the square wave voltage is low, and keep, by the first circuit, a gate-source voltage of the first transistor below a first threshold voltage of the first transistor; and
add the high voltage to the portion of the fixed voltage of the first capacitor when the square wave voltage is high, and increase the gate-source voltage of the first transistor above the first threshold voltage, so that the high voltage and the portion of the fixed voltage of the first capacitor is provided through the transistor as an output voltage of the drive voltage generator; and
wherein the generator is further configured to:
load the second capacitor by the second circuit with a portion of the high voltage when the square wave voltage is high, and keep, by the second circuit, a gate-source voltage of the second transistor below a second threshold voltage of the first transistor; and
reduce by the square wave input and the second circuit, the load of the second capacitor by a difference between the high voltage and the low voltage of the square wave so that the load of the second capacitor becomes a negative voltage when the square wave voltage is low, and increase the gate-source voltage of the second transistor above the second threshold voltage, so that the negative voltage of the second capacitor is provided through the second transistor as an output voltage of the drive voltage generator.

2. The drive voltage generator according to claim 1, wherein the high voltage is 3.3V and the low voltage is 0V.

3. The drive voltage generator according to claim 1, wherein the first circuit further comprises a series connection of a regular diode and a Zener diode connected to the fixed voltage.

4. The drive voltage generator according to claim 1, wherein the second circuit further comprises a series connection of a regular diode and a Zener diode connected to a ground.

5. The drive voltage generator according to claim 1, wherein the square wave voltage is provided by a microcontroller.

6. The drive voltage generator according to claim 1, wherein the first transistor and second transistor are bipolar junction transistors, and wherein the gate-source voltage is a base-emitter voltage.

7. The drive voltage generator according to claim 2, wherein the first circuit further comprises a series connection of a regular diode and a Zener diode connected to the fixed voltage.

8. The drive voltage generator according to claim 2, wherein the second circuit further comprises a series connection of a regular diode and a Zener diode connected to a ground.

9. The drive voltage generator according to claim 2, wherein the square wave voltage is provided by a microcontroller.

10. The drive voltage generator according to claim 2, wherein the first transistor and second transistor are bipolar junction transistors, and wherein the gate-source voltage is a base-emitter voltage.

11. The drive voltage generator according to claim 2, wherein the output voltage is in a range of −1.5V to −3.3V, when the square wave voltage is low.

12. The drive voltage generator according to claim 2, wherein the output voltage is in a range from 4.5V to 6.6V, when the square wave voltage is high.

13. The drive voltage generator according to claim 12, wherein the output voltage is in a range from 5V to 6.6V.

14. The drive voltage generator according to claim 12, wherein the output voltage is in a range of −1.5V to −3.3V, when the square wave voltage is low.

15. The drive voltage generator according to claim 13, wherein the output voltage is in a range of −1.5V to −3.3V, when the square wave voltage is low.

16. The drive voltage generator according to claim 14, wherein the output voltage is in a range from −2V to −3V.

17. A GaN high electron mobility transistor unit comprising:
a GaN high electron mobility transistor; and
the drive voltage generator according to claim 1, wherein the drive voltage generator is connected to the GaN high electron mobility transistor, and wherein the output voltage of the drive voltage generator is a supply voltage to the GaN high electron mobility transistor.

18. A method for generating a drive voltage for a GaN high electron mobility transistor, comprising the steps of:
receiving a fixed voltage;
receiving a square wave voltage alternating between a high voltage and a low voltage;
loading by a first circuit connected to a first capacitor, the first capacitor with a portion of the fixed voltage when the square wave voltage is low, and keeping, by the first circuit, a gate-source voltage of a first transistor connected to the first capacitor and the first circuit below a first threshold voltage of the first transistor; and
adding the high voltage to the portion of the fixed voltage of the first capacitor when the square wave voltage is high, and increasing the gate-source voltage of the first transistor above the first threshold voltage, so that the high voltage and the portion of the fixed voltage of the first capacitor is provided through the transistor as an output voltage of the drive voltage generator;
loading by a second circuit, a second capacitor connected to the second circuit, with a portion of the high voltage when the square wave voltage is high, and keeping, by the second circuit, a gate-source voltage of a second transistor connected to the second capacitor and the second circuit below a second threshold voltage of the second transistor; and
reducing by the square wave voltage and the second circuit, the load of the second capacitor by a difference between the high voltage and the low voltage of the square wave so that the load of the second capacitor becomes a negative voltage when the square wave voltage is low, and increasing the gate-source voltage of the second transistor above the second threshold voltage, so that the negative voltage of the second capacitor is provided through the second transistor as an output voltage of the drive voltage generator.
